(19) United States
(12) Patent Application Publication
(10) Pub. No.: US 2025/0350094 A1
(43) Pub. Date: Nov. 13, 2025

(54) LASER MODULE AND LASER COUPLING SYSTEM

(71) Applicant: Institute of Physics, Chinese Academy of Sciences, Beijing (CN)

(72) Inventors: Ling LU, Beijing (CN); Yan Li, Beijing (CN); Zongliang LI, Beijing (CN); Tianwei Zheng, Beijing (CN); Guangrui LI, Beijing (GB); Lechen Yang, Beijing (GB)

(21) Appl. No.: 19/199,614

(22) Filed: May 6, 2025

(30) Foreign Application Priority Data
May 9, 2024 (CN) 202410571517.X
Dec. 5, 2024 (CN) 202411776355.X

(51) Int. Cl. H01S 5/183; H01S 5/02251; H01S 5/026; H01S 5/11

(52) U.S. Cl. CPC H01S 5/18388; H01S 5/02251; H01S 5/026; H01S 5/11

(57) ABSTRACT

Disclosed is a surface-emitting laser module integrated with a metalens, and an electronic device and a laser coupling system comprising the surface-emitting laser module. According to an embodiment, a surface-emitting laser module may comprises: a surface-emitting laser comprising a photonic crystal surface-emitting laser or a topological cavity surface-emitting laser, the surface-emitting laser having a light-emitting surface; and a metalens integrated at the light-emitting surface of the surface-emitting laser.

### CROSS-REFERENCE TO RELATED APPLICATIONS

The present application claims the right of priority of Chinese patent application CN202410571517.X filed on May 9, 2024, and Chinese patent application CN202411776355.X filed on Dec. 5, 2024, the disclosure of which are incorporated herein by reference in their entireties.

### TECHNICAL FIELD

The present disclosure generally relates to the field of photoelectric devices, and in particular to a surface-emitting laser module with integrated metalens and a laser coupling system comprising the laser module, which can realize miniaturization and integration of a semiconductor laser module and related optical communication device(s).

### BACKGROUND

The semiconductor laser has been widely used in many fields such as communication, medical treatment, display, and material processing because of the advantages thereof of small volume, high efficiency, low power consumption, long service life, low cost, and the like. However, the laser chip per se is generally difficult to use individually and needs to be matched with various optical elements, such as a lens, prism, diffractive element, polarization element, and the like, to form a laser module, so that the emitted light beam can meet the application requirements. The volume of these optical elements is not only much larger than that of semiconductor laser chips, but the manufacturing and packaging cost thereof also tends to exceed the laser chips per se, so that the volume and the price of the whole semiconductor laser module are difficult to further reduce, which limits the application of the more integration and lower cost of the semiconductor laser light source.

The volume of the laser module can be calculated as the product of the light emission area and the propagation length. The light emission area is generally determined by the application requirements and the diffraction limit, which cannot be reduced, for example, due to the fact that both the divergence angle and the far-field resolution of the light beam are determined by the near-field area. Therefore, further miniaturization of the laser module can only depend on reduction of the propagation length. At present, the required propagation length of the laser module is mainly used for beam expansion and shaping of the semiconductor laser spot. The reason is that the emission aperture of the semiconductor laser chip is generally much smaller than the emission aperture required for the application. For example, the beam aperture of the lattice structure laser module used for face recognition is about 2 mm, while the near-field light spot of the single vertical cavity surface-emitting laser (VCSEL) is about 10 m, which needs to propagate a large distance to accomplish beam expansion.

FIG. 1A is a schematic structural diagram of a conventional semiconductor laser module. As shown, a plurality of vertical cavity surface-emitting lasers (VCSEL) 101 may be arranged in an array to provide a light beam with sufficiently high power. A plurality of optical elements, such as a lens group formed by a plurality of lenses 102a, 102b, and 102c, and a diffractive optical element (DOE) 102d are provided above the plurality of VCSEL. In the example shown in FIG. 1A, in order to provide an emission light spot of about 2 mm×2 mm, a propagation length of more than 3 mm is needed, and thus the volume of the whole laser module is relatively large.

FIG. 1B shows a schematic structural diagram of a semiconductor laser module including a metalens (also referred to as a metasurface) 103 in the latest development. The metalens is a planar optical technology, that can replace conventional passive optical elements such as concave and convex lenses, and the thickness can be reduced to the wavelength magnitude, but this is still a very limited reduction in the size of the existing laser module, because a long propagation distance is still required between the laser and the metalens for beam expansion, and the size of the laser module is still determined by the aperture of the emission light spot. As shown in FIG. 1B, in a case where the array of the same vertical cavity surface-emitting laser 101 is used, in order to provide an emission light spot of about 2 mm×2 mm, the beam propagation length for beam expansion is still about 3 mm, and thus the size reduction of the whole laser module is very limited.

In addition, directly integrating the metalens on the light-emitting surface of the vertical cavity surface-emitting laser cannot reduce the size of the laser module, because the emission area of the single vertical cavity surface-emitting laser 101 is too small, and the emitted beam is far from meeting the requirements of practical application, and thus a large beam expansion distance is still required. Therefore, the fundamental obstruction to the miniaturization of laser modules is still the lack of high-performance semiconductor lasers whose near-field light spot can be matched to the required emission aperture.

### SUMMARY

The present disclosure provides a miniaturized module of a surface-emitting laser with an integrated metalens as well as a laser coupling system, which can solve one or more of the above-mentioned technical problems.

According to an aspect of the present disclosure, a surface-emitting laser module integrated with a metalens is provided, comprising: a surface-emitting laser comprising a photonic crystal surface-emitting laser or a topological cavity surface-emitting laser, the surface-emitting laser having a light-emitting surface; and a metalens integrated at the light-emitting surface of the surface-emitting laser.

According to an aspect of the present disclosure, an electronic device is provided, which comprises the above-mentioned surface-emitting laser module.

According to an aspect of the present disclosure, a laser coupling system is provided, comprising: the above-mentioned surface-emitting laser module, wherein the metalens in the surface-emitting laser module is used for focusing a light beam emitted from the light-emitting surface; and an optical fiber or on-chip optical waveguide configured to couple with the focused light beam.

Based on some embodiments, the present disclosure directly integrates a metalens on a light-emitting surface of a photonic crystal surface-emitting laser or a topological cavity surface-emitting laser. Both the photonic crystal surface-emitting laser or the topological cavity surface-emitting laser can provide large-area single-mode laser, achieving millimeter-level aperture and watt-level output power, while the metalens can modulate the emission optical field in any degree of freedom such as phase, polarization and emission angle, and the like, so as to realize a desired emission light beam.

Therefore, the present disclosure provides a possibility of simplifying and downsizing the laser module and the optical fiber/on-chip optical waveguide communication device. The metalens can be directly integrated into the light emission surface of the photonic crystal surface-emitting laser or the topological cavity surface-emitting laser. For example, a micro-nano structure is directly etched into the semiconductor layer on the emission surface to form the metalens. Alternatively, an additional metalens layer can be deposited on the light emission surface of the photonic crystal surface-emitting laser or the topological cavity surface-emitting laser, and the micro-nano structure is etched in the metalens layer to form a metalens, or the micro-nano structure can also be directly deposited, grown or epitaxialized on the light-emitting surface of the surface-emitting laser to form the metalens. According to the present disclosure, a high-performance semiconductor laser whose near-field light spot can be matched with the required emission aperture can be provided, and the planarization and integration of the whole semiconductor laser light source are realized, and the volume thereof is reduced by more than one order of magnitude compared to existing semiconductor laser modules.

The above and other features and advantages of this application will become apparent from the description of exemplary embodiments in conjunction with the accompanying drawings below.

### BRIEF DESCRIPTION OF THE DRAWINGS

FIG. 1A is a schematic structural diagram of an existing semiconductor laser module.

FIG. 1B is a schematic structural diagram of another existing semiconductor laser module.

FIG. 2 is a schematic structural diagram of a semiconductor laser module according to an exemplary embodiment of the present disclosure.

FIG. 3 is a schematic diagram of a layered structure of a semiconductor laser module according to an exemplary embodiment of the present disclosure.

FIG. 4 is a schematic diagram of a layered structure of a semiconductor laser module according to another exemplary embodiment of the present disclosure.

FIG. 5 is a schematic diagram of a nanopillar structure forming a metalens according to an exemplary embodiment of the present disclosure.

FIG. 6 is a relationship curve of parameters of a nanopillar structure of a metalens on the modulation of phase, wavelength and transmittance of the emission beam according to an exemplary embodiment of the present disclosure.

FIG. 7 is an electron micrograph of a nanopillar structure forming a metalens according to an exemplary embodiment of the present disclosure.

FIG. 8 is a simulation pattern and an experimental photograph of a point cloud structure and a far-field pattern realized by using a semiconductor laser module according to an exemplary embodiment of the present disclosure.

FIG. 9A is a schematic structural diagram of an existing system for coupling semiconductor laser with an optical fiber.

FIGS. 9B-9C are schematic structural diagrams of an existing system for coupling semiconductor laser with an on-chip optical waveguide.

FIG. 10A is a schematic structural diagram of a system for coupling semiconductor laser with an optical fiber according to an exemplary embodiment of the present disclosure.

FIGS. 10B-10C are schematic structural diagrams of a system for coupling a semiconductor laser with an on-chip optical waveguide according to an exemplary embodiment of the present disclosure, wherein the coupling modes are edge coupling and surface coupling, respectively.

FIGS. 11A-11B are three-dimensional space structural schematic diagrams of a system for coupling a semiconductor laser with an optical fiber/on-chip optical waveguide according to an exemplary embodiment of the present disclosure.

FIG. 12 is an electron micrograph of a nanopillar structure forming a metalens according to an exemplary embodiment of the present disclosure.

FIG. 13 is schematic diagram of an optical test mounting structure according to an exemplary embodiment of the present disclosure.

FIGS. 14A-14B are schematic diagrams of parameters for performing optical test to the device according to an exemplary embodiment of the present disclosure.

FIGS. 15A-15C show curves of a tolerance test of the coupling system.

### DETAILED DESCRIPTION

Exemplary embodiments of the present disclosure will be described below with reference to the accompanying drawings. It should be noted that the drawings may not be drawn to scale.

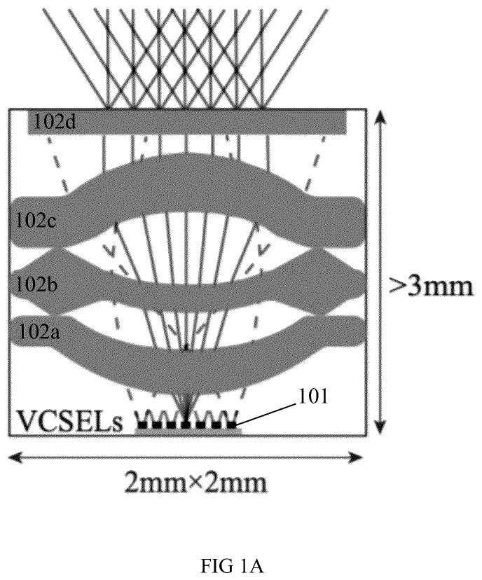

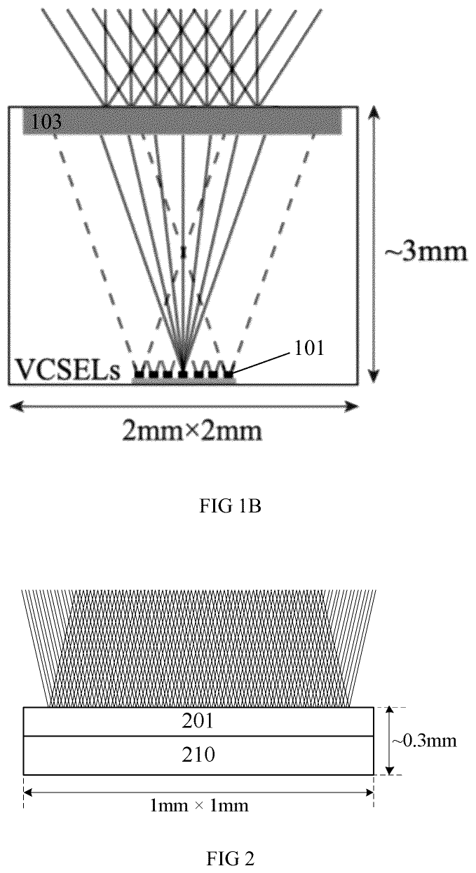

FIG. 2 is a schematic structural diagram of a semiconductor laser module according to an exemplary embodiment of the present disclosure. As shown in FIG. 2, the semiconductor laser module comprises a surface-emitting laser 210, which may be a photonic crystal surface-emitting laser (PCSEL) or a topological cavity surface-emitting laser (TCSEL). The surface-emitting laser 210 has a light-emitting surface, which is shown as the upper surface in FIG. 2. A metalens 201 is integrated at the light-emitting surface of the surface-emitting laser 210. Compared to a vertical cavity surface emitting laser (VCSEL), the photonic crystal surface-emitting laser (PCSEL) and the topological cavity surface-emitting laser (TCSEL) can provide a larger light-emitting surface which, for example, may have a millimeter-level aperture. Therefore, by integrating the metalens 201 on the single surface-emitting laser 210, it is possible to manipulate the emission light field at arbitrary degree of freedom, and provide a good coherent light source. In the embodiment of FIG. 2, for example, by selecting and using a PCSEL or TCSEL laser with a surface size of approximately 1 mm×1 mm, the emission beam aperture equivalent to the laser module based on the VCSEL array shown in FIG. 1A and FIG. 1B can be realized, and the thickness of the laser module can be reduced to approximately 0.3 mm, so that the volume of the whole laser module can be reduced by more than one order of magnitude, and the planarization and integration of the whole semiconductor laser light source are realized.

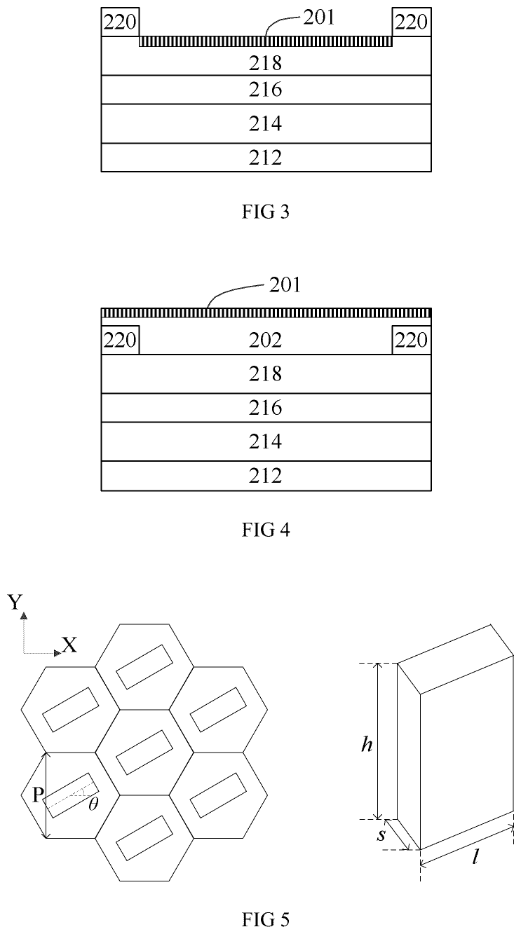

FIG. 3 is a schematic diagram of a layered structure of a semiconductor laser module according to an exemplary embodiment of the present disclosure. As shown in FIG. 3, the semiconductor laser module may include a bottom electrode layer 212, a first semiconductor layer 214, an active layer 216, a second semiconductor layer 218, and a top electrode layer 220, which constitute the surface-emitting laser 210 shown in FIG. 2. The first semiconductor layer 214 and the second semiconductor layer 218 may have different conductive types. For example, the first semiconductor layer 214 may be an N-type doped semiconductor layer, the second semiconductor layer 218 may be a P-type doped semiconductor layer, or vice versa, and thus respectively inject N-type carriers and P-type carriers into the active layer 216. For a photonic crystal surface-emitting laser (PCSEL), the active layer 216 includes a photonic crystal layer formed therein or in the vicinity thereof (e.g. at the upper surface or the lower surface), which includes a semiconductor material, and a spatial periodic structure formed by a material with different refractive indexes, such as air, in the semiconductor material. The air holes are arranged in a spatial periodicity, so that the light refractive index generates periodic distribution, and the light generates an energy band structure when the light propagates therein. The photon frequency in the bandgap is inhibited from propagating, and thus a high-efficiency zero-threshold semiconductor laser is prepared by using this characteristic. For a topological cavity surface-emitting laser (TCSEL), the active layer 216 similarly also includes a photonic crystal layer formed therein or in its vicinity (e.g. at the upper surface or the lower surface), wherein the photonic crystal supercell structure is further modulated in two separate dimensions so as to generate a vortex-type structure change around the center of the photonic crystal cavity, thus opening up Dirac points in the energy band of the photonic crystal supercell in the equilibrium position. Thus, the photonic crystal layer can also be referred to as a topological photonic crystal layer. Herein for simplicity, only the active layer 216 is shown in FIG. 3, and an individual photonic crystal layer or topological photonic crystal layer is not shown. However, it is to be understood that a photonic crystal layer or a topological photonic crystal layer is formed in or near the active layer 216.

Continuing with reference to FIG. 3, the bottom electrode layer 212 and the top electrode layer 220 may be formed of a conductive metal material. In order to facilitate laser emission, the top electrode layer 220 may be formed in a ring shape; in some other embodiments, the top electrode layer 220 may also be formed in a porous structure or a mesh structure. Alternatively, when the top electrode layer 220 is formed from a transparent conductive material such as IZO, ITO, the top electrode layer 220 may also be formed as a complete layer. For another example, the top electrode layer 220 may also include a very thin metal layer, so that the laser may pass through the top electrode layer 220 to be emitted.

It should be understood that FIG. 3 only shows the basic layer structure of the photonic crystal surface-emitting laser (PCSEL) and the topological cavity surface-emitting laser (TCSEL), and they may further include various additional layers, such as a Bragg reflecting layer, a buffer layer, a protective layer, and the like, and that the present disclosure is not limited to the photonic crystal surface-emitting laser (PCSEL) and the topological cavity surface-emitting laser (TCSEL) of a specific structure. Rather, the photonic crystal surface-emitting laser (PCSEL) and the topological cavity surface-emitting laser (TCSEL) of various structures can both be used as the surface-emitting laser 210 in the semiconductor laser module of the present disclosure. It is to be understood that various existing or future-developed photonic crystal surface-emitting lasers (PCSEL) and topological cavity surface-emitting lasers (TCSEL) can be applied in the miniaturization module of the surface emitting laser integrated with a metalens provided by the present disclosure as long as they can provide a size of the near-field light spot which meets the needs of the application.

In the embodiment shown in FIG. 3, because the top electrode layer 220 is formed in a ring shape, the second semiconductor layer 218 can be regarded as a top layer of the surface-emitting laser 210, and the upper surface thereof is used as a light-emitting surface of the surface-emitting laser 210. The metalens 201 may be integrated in an upper surface of the second semiconductor layer 218, including a nanopillar structure formed in the surface, which will be described in detail below. In some other embodiments, the top layer of the surface-emitting laser 210, i.e., the layer forming the light-emitting surface, may be other layers, such as other semiconductor layer, or may be an insulation protection layer, a metal layer used as a top electrode, and the like. In this case, the metalens 201 can be integrated in the upper surface of the conductor layer, the insulation protection layer or the top electrode metal layer. For example, the top layer of the surface-emitting laser 210 can be directly etched to form the nanopillar structure of the metalens 201. A portion of the depth of the top layer can be etched, or the whole depth of the top layer can be etched in a case where the function of the top layer is not affected.

FIG. 4 is a schematic diagram of a layered structure of a semiconductor laser module according to another exemplary embodiment of the present disclosure. In the embodiment shown in FIG. 4, the structure of the surface-emitting laser 210 is substantially the same as the embodiment shown in FIG. 3, comprising a bottom electrode layer 212, a first semiconductor layer 214, an active layer 216, a second semiconductor layer 218, and a top electrode layer 220, so repeated description of these layers will be omitted here. Referring to FIG. 4, the semiconductor laser module further comprises a metalens layer 202 formed on the top layer (a second semiconductor layer 218 shown in FIG. 4) of the surface-emitting laser 210, wherein the nanopillar structure of the metalens 201 is formed in the upper surface of the metalens layer 202. Herein, the metalens layer 202 can also be regarded as a portion of the metalens 201. Although FIG. 4 shows that only a portion of the thickness of the metalens layer 202 is etched to form a nanopillar structure, in other embodiments, the entire thickness of the metalens layer 202 may also be etched to form a nanopillar structure. That is, the metalens layer 202 and the nanopillar structure are the same layer. In the embodiment shown in FIG. 4, the metalens layer 202 is directly deposited on the top layer of the surface-emitting laser 210. In other embodiments, a transparent intermediate layer may also exist between the metalens layer 202 and the top layer of the surface-emitting laser 210. Herein, integrating the metalens 201 into the light-emitting surface of the surface-emitting laser means that there is direct or indirect contact between the two, but there is no interval or gap for beam expansion as in the prior art. The metalens layer 202 may include a semiconductor material, an insulator material, a metallic material, an organic material or a transparent conductive material, and the like, examples of which include, but are not limited to, one or more of amorphous silicon, titanium dioxide, silicon nitride, silicon oxide, silicon oxide, alumina, hafnium dioxide, gold, silver, polyaniline, polypyrrole, polythiophene and poly-p-styrene, IZO, ITO. In one embodiment, in order to form a good interface with the second semiconductor layer 218 to reduce reflection, the metalens layer 202 may include a silicon material, such as amorphous silicon.

In addition to firstly forming the metalens layer 202, and then etching out the nanopillar structure to form the metalens 201 as shown in FIG. 4, in some other embodiments, the nanopillar structure can also be directly deposited, grown, or epitaxialized on the light-emitting surface of the surface-emitting laser 210. For example, a sacrificial layer, such as a photoresist layer, may be formed on the light-emitting surface of the surface-emitting laser 210, in which an opening of a desired pattern may be formed through a photolithography (e.g. UV lithography, electron beam lithography) or etching process (e.g. dry etching) to expose the light-emitting surface below. Then the nanopillar structure is deposited, grown, or epitaxialized. Finally the sacrificial layer, such as the photoresist layer, is removed, leaving behind the nanopillar structure to form the metalens 201.

In some exemplary embodiments, the metalens 201 may be directly formed in the top layer of the surface-emitting laser 210 or in the upper surface of the metalens layer 202 by an etching process. Therefore, the step of forming the metalens 201 can be integrated into the process of forming the surface-emitting laser 210, and then finally cutting out a single surface-emitting laser 210. In this way, the surface-emitting laser 210 and the metalens 201 integrated thereon can be formed in a self-aligned manner. In some other embodiments, it is also possible to etch the top layer of the surface-emitting laser 210 after completing the fabrication of the surface-emitting laser 210 and cutting out a single surface-emitting laser 210, or depositing the metalens layer thereon and etching the metalens layer, in order to prepare the metalens 201. According to the present disclosure, the metalens is prepared by a simpler and more economical process, compared to the conventional patching mode by which a pre-prepared metalens is bonded to the surface-emitting laser 210 leading to an additional packaging alignment cost, unnecessary waste on the volume and the substrate material, and interface reflection problem.

In various embodiments described above with reference to FIG. 3 and FIG. 4, a protective layer may also be formed on the metalens 201 to protect the nanopillar structure of the metalens 201. Such a protective layer may be formed from a transparent material, and have a refractive index that is different from the refractive index of the material forming the metalens 201. For example, the refractive index of the protective layer may be significantly greater than or less than the refractive index of the material forming the metalens 201.

It should be understood that, throughout the present disclosure, the formation of nanopillar structure of the metalens 201 also encompasses the formation mode of the nanopore. The nanopore can be regarded as a nanopillar formed by air or vacuum. For example, a metalens layer 202 may be first formed and then etched therein to form a nanopore structure. The modulation of light by the nanopores is based on the same principle as that of the nanopillar, and details of which will not be repeated herein. Therefore, when a nanopillar or a nano-unit is mentioned in the present disclosure, it may also comprise a nanopore.

FIG. 5 is a schematic diagram of a nanopillar structure forming a metalens 201 according to an exemplary embodiment of the present disclosure. As shown in FIG. 5, the metalens 201 may include a rectangular nanopillar structure. However, the nanopillar structure may also have other shapes, such as, but not limited to, elliptical shapes. A plurality of nanopillar structures can be periodically arranged, for example, periodically arranged according to a two-dimensional triangular lattice (as shown in the left part of FIG. 5) or a tetragonal lattice (not shown), with an arrangement period of P Each nanopillar structure may have a height h, a length 1, a width s (as shown in the right part of FIG. 5), and may also have a rotation angle θ. The rotation angle θ is an angle of rotation of the nanopillar structure relative to a predetermined reference direction in a two-dimensional plane. One or more of the height h, the length l, the width s, and the rotation angle θ of the nanopillar structure can be modulated to adjust a phase, intensity, and/or polarization of a laser emitted from the surface-emitting laser module. Taking the rectangular nanopillar structure shown in FIG. 5 as an example, the material thereof is amorphous silicon with a refractive index of 3.34, and the nanopillar structure is located on the second semiconductor layer 218 formed by InP. When one beam of light is incident on the nanopillar structure along the z-direction, the relationship between the emission light field

$$( {E}_{x}^{out} , {E}_{y}^{out} )$$

and the incident light field

$$( {E}_{x}^{in} , {E}_{y}^{in} )$$

can be expressed as follows:

$$[ \begin{matrix}{E}_{x}^{out} \\ {E}_{y}^{out}\end{matrix} ] = R ( - θ ) [ \begin{matrix}{t}_{l} & 0 \\ 0 & {t}_{s}\end{matrix} ] R ( θ ) [ \begin{matrix}{E}_{x}^{in} \\ {E}_{y}^{in}\end{matrix} ] \qquad ( formula 1 )$$

wherein tₗ and tₛ are transmission coefficients of light polarized along the l direction and polarized along the s direction

$$( {t}_{l} = \vert {t}_{l} \vert {e}^{i {∅}_{l}} , {t}_{s} = \vert {t}_{s} \vert {e}^{i {∅}_{s}} ) , R ( θ ) = [ \begin{matrix}cos ( θ ) & sin ( θ ) \\ - sin ( θ ) & cos ( θ )\end{matrix} ]$$

rotation matrix, θ is the angle between the slow axis of the nanopillar and a predetermined X-axis direction. In a case where the incident optical field Eⁱⁿ is determined, the nanopillar can modulate the arbitrary incident optical field Eⁱⁿ into an emission optical field E^{out} of arbitrary phase and arbitrary polarization under near lossless conditions by selecting the parameters l, s and θ. A photonic crystal surface-emitting laser (PCSEL) and a topological cavity surface-emitting laser (TCSEL), which are used as a surface-emitting laser 210, are both single-mode lasers with a determined incident phase and polarization. So, an emission light beam of arbitrary phase and polarization can be emitted by combining the metalens 201 with the surface-emitting laser 210.

Taking the application of holographic patterns as an example, when a topological cavity surface-emitting laser (TCSEL) is used as the surface-emitting laser, the light beam emitted after passing through the resonant cavity is a radially polarized vector light beam. In order to obtain a higher-quality dot matrix cloud and a clearer hologram in the application, the polarization of the light beam needs to be regulated to be consistent in the first place. Taking the modulation into circularly polarized light as an example, a series of combination of side lengths l and s need to be selected, so that the transmission phase Øₗ in the long-axis direction and the transmission phase Øₛ in the short-axis direction satisfy Øₗ−Øₛ=π/2, and the rotation angle θ of the nanopillar is selected to be π/4 with respect to the direction of polarization, so that the rectangular nanopillar plays a role of ¼ waveplate, which can regulate the linearly polarized light at each position of the vector light beam to circularly polarized light, while the Øₛ spreads over the phase from 0 to 2π, so that the circularly polarized light has an arbitrary emission phase.

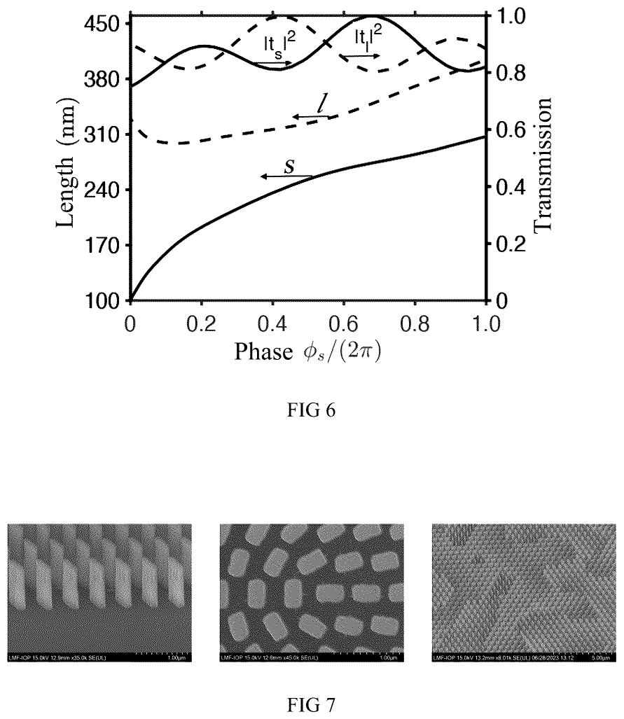

In order to ensure that there is no high-order reflection, the arrangement period P of the nanopillar structure should be less than

$$\frac{2}{\sqrt{3}} \frac{λ}{{n}_{lnP}} ,$$

where n_{Inp} is the refractive index of InP. The period P is chosen to be, for example, 558 nm, the height h of the nanopillar is 1.5 m, the length of the rectangular short-edge s ranges from 100 nm to 300 nm, and the length of the long edge 1 ranges from 300 nm to 400 nm. Then, according to the Fourier iteration algorithm, the emission phases at different positions are designed. The corresponding relationship between the rectangular parameters, the emission intensity and the emission phase is shown in FIG. 6, which shows that the transmittance is basically more than 80%, exceeding a transmittance of 73% from the InP substrate per se into the air, which implies that the surface integration of the metalens 201 also serves as a transmittance-enhancing film.

FIG. 7 is an electron micrograph of a nanopillar structure forming the metalens 201. The example shows a nanopillar structure obtained through an electron-beam exposure and dry etching process after depositing amorphous silicon on an InP substrate (e.g. a second semiconductor layer 218). Selecting the amorphous silicon to form the metalens is out of a comprehensive consideration for processing difficulty and modulation efficiency. However, in other embodiments, other materials may also be used, or the nanopillar structure may be formed by directly etching on the top layer (e.g. an InP semiconductor layer or a top electrode metal layer) of the surface-emitting laser 210, where the processing precision mainly depends on the etching precision. When the metalens 201 is formed in the top electrode metal layer formed as a continuous layer, the top electrode metal layer serves to modulate the light beam and introduce the current at the same time, so that the current injection is more uniform, but the transmittance of the emission light beam may be affected to a certain extent due to the high light absorption rate of the metal.

The semiconductor laser module of the present disclosure has a wide range of application prospect. In an exemplary application scenario, when the semiconductor laser module uses a TCSEL laser, due to the polarization single-mode characteristic of TCSEL and the polarization modulation capability of the metalens, the TCSEL laser with the integrated metalens may realize an output of arbitrarily determined polarization, which is advantageous compared to the multi-mode VCSEL laser or single-mode VCSEL laser with polarization degeneracy. For example, a TCSEL laser with integrated metalens can output common linear polarization Gaussian beams and can also output circularly polarized lasers which are generally difficult to achieve on-chip. A more general polarized light beam is a cylindrical vector vortex beam (CVVB), which is a cylindrical light beam with inconsistent phase and polarization distribution in space, and can be expressed as Jones vector in the form of two parameters 1 and m, namely

$${E}_{l , m} = {E}_{0} ( r ) {e}^{ila} [ \begin{matrix}cos ( ma ) \\ sin ( ma )\end{matrix} ] . \qquad ( formula 2 )$$

Such light beams have exotic optical properties, and have potential application prospect in the fields of optical communication, optical trapping, quantum information and the like. In fact, the light beam emitted from the TCSEL laser per se can be regarded as a cylindrical vector vortex beam with l=0, m=1, and the metalens has the capability to modulate the polarization and phase arbitrarily, so that the TCSEL laser with integrated metalens can also emit a light beam with arbitrary (l, m). The simplest modulation is to convert a hollow beam into the Gaussian fundamental mode beam (which has extensive application prospect) with (l=0, m=0), by simply adjusting the polarization of each position to the same direction, with the phase unchanged. In this case, the divergence angle is decreased to half of the original, and the laser brightness is increased to 4 times of the original, and the M2 factor (i.e. laser beam quality factor) is close to 1, which verifies the single-mode resonance characteristics of TCSEL laser. The micro-nano processing pattern of the metalens is shown in the middle pattern in FIG. 7.

For the semiconductor laser module of the present disclosure with directly integrated metalens on the PCSEL or TCSEL laser, in addition to polarization control, the semiconductor laser module has potential applications in the aspects of structured light control, holographic patterning and the like. Projecting a known pattern onto a target object, and then three-dimensional information of the object is obtained by measuring the deformation of the pattern. This technology is called structured light technology, which can be applied to the fields of face recognition, three-dimensional surveying and mapping and the like. A common structured light is a dense dot matrix, such as that used for face identity recognition (face ID) commonly used on a mobile phone. At present, a structured light generation module on a consumer-grade electronic device is usually composed of a VCSEL laser array, a set of lens, diffractive optics and other components. As shown in FIG. 1A, the laser is collimated and expanded by the lens set and then is beam-split through DOE to form a dot matrix cloud. According to different demand scenarios, the divergence angle of a single emission point ranges from about 0.1° to 1°. In order to achieve such a small divergence angle, the size of the light-emitting aperture size is usually about 2 mm. In this structure, various optical elements need to be strictly aligned and occupy a large volume. To address this problem, Metalenz company has introduced Orion product based on the metasurface, as shown in FIG. 1B. Due to the arbitrary phase design capability of the metasurface, the function of collimation and dot-matrix emission can be completed through one layer of metasurface, which can replace the bulky lens set and DOE in a traditional module. Although the Orion module has a simpler structure than a traditional module, the volume is not obviously reduced, because the light-emitting aperture of the VCSEL is too small, so a relatively large space is still needed between the VCSEL and the metasurface for the beam expansion of light beam emitted by the VCSEL, so as to realize the small divergence angle of a single emission point. By contrast, PCSEL and TCSEL have the characteristics of a large light-emitting area and a small divergence angle, so that the steps of beam expansion and collimation can be avoided after the metalens is etched out, and structured light emission can be accomplished directly, as shown in FIG. 2. The advantages of the PCSEL and TCSEL laser module integrated with a metalens of the present disclosure on the dot matrix projector will be described below from five aspects: volume, packaging, dot matrix quality, polarization and wavelength.

### Volume

As shown in FIG. 2, the PCSEL or TCSEL laser module with integrated metalens has been miniaturized to the extreme, where the whole module only needs one semiconductor chip approximately one hundred microns thick, and the area of the chip is determined by the diffraction limit of the application requirement. Referring to FIGS. 1A, 1B and FIG. 2, the longitudinal thickness of the laser module of the present disclosure is reduced by about one order of magnitude, and the transverse area is also reduced to about one quarter, as compared to a traditional module. The reduction in thickness is due to the large-area single-mode resonant cavities of PCSEL and TCSEL lasers, which have a divergence angle of 1° or less, eliminating the need for laser beam expansion. The integration of the metalens on the emission surface of the laser also minimizes the thickness of the optical components. The reduction in the transverse area is due to the effective coverage for the beam by the metalens and the high-quality beam from the PCSEL and the TCSEL lasers per se, so that the transverse light-emitting area is minimized to the limit of transverse dimensions of the semiconductor laser light source. The reduction in volume by about 40 times can also results in a significant reduction in weight.

### Packaging

A conventional dot matrix cloud emitter is composed of optical components such as a VCSEL laser array, a lens set, and a DOE, as shown in FIG. 1A. In order to ensure the collimation of the light beam and the uniformity of the dot matrix, strict alignment needs to be performed between various optical elements and the lasers, which requires a high level of packaging. In contrast, the PCSEL/TCSEL laser module with integrated metalens of the present disclosure is integrated in a single chip, which eliminates the step of assembling different optical elements, resulting in a lower cost. Meanwhile, conventional packaging methods such as glue bonding will also face various problems such as aging of fixtures, poor temperature stability, and interface reflection, whereas the PCSEL/TCSEL laser module with directly integrated metalens of the present disclosure has a relatively long service lifetime, better stability, and better light-emitting efficiency.

### Dot Matrix Quality

The dot matrix distribution based on VCSEL laser array always inevitably has traces of replicated splicing, which leads to uneven distortion or overlapping of point cloud image at the splicing edge, increasing the difficulty of subsequent algorithm processing. In contrast, the dot matrix emitted by the PCSEL/TCSEL laser module with integrated metalens of the present disclosure is generated by a collimated beam, which produces a more uniform dot matrix. A major advantage of the metalens as a diffractive optical element is that it has a smaller modulation unit, and therefore has a larger field of view (FOV) than a conventional diffractive optical element DOE.

### Polarization

Most of the currently used VCSEL lasers are multi-mode VCSEL lasers without polarization selectivity that emit far field light of uncertain polarization, whereas PCSEL/TCSEL lasers have a deterministic single-mode polarization state, and thus the far field of the PCSEL/TCSEL laser module with integrated metalens also has deterministic polarization. If linearly polarized light or circularly polarized light in a specific direction is emitted, stray light of other polarization can be filtered out at a receiving end, or polarization information of a detected object can be obtained.

### Wavelength

The PCSEL/TCSEL laser module with integrated metalens of the present disclosure can realize emission light of a specific wavelength. For example, 1550 nm wavelength laser can be easily realized. Compared with 940 nm wavelength, which is the most widely used wavelength in the 3D sensing field at present, 1550 nm wavelength has three advantages: firstly, it is more eye-safe. Compared with 940 nm. the safety threshold of the human eye for 1550 nm continuous wave is improved by one to two orders of magnitude, and the pulse peak power threshold is increased by five orders of magnitude, so that higher power emission laser can be used with a longer detection distance; secondly, the 1550 nm stray light in the natural environment is relatively weak, so higher contrast ratio during detection will make structured light detection more accurate; thirdly, 1550 nm wavelength has a higher transmittance to the current mainstream OLED screen, so that it has a broad application prospect in developing under-screen structured light. Because it is difficult for VCSEL to achieve long wavelengths, current 1550 nm 3D sensing devices mostly uses side-emitting DFB (distributed feedback) lasers as light sources. Side-emitting module is more complex than surface-emitting modules. Further, the DFB laser emits elliptical beams, which require cylindrical lens for modulation and collimation. Accordingly, in comparison to this, the advantages of the PCSEL/TCSEL laser module with integrated metalens of the present disclosure are more obvious.

The dot matrix structured light is only one representative application instance of the PCSEL/TCSEL laser module with integrated metalens of the present disclosure. In addition, a wide variety of far-field functions can be realized, including light deflection, uniform planar light emission, holographic imaging and the like. The laser beam can be directly and obliquely emitted, so that the array of the PCSEL/TCSEL laser module with integrated metalens can realize the functions of all-solid-state laser radar and the like. Its phase design is also very simple. When the deflection angle is φ, the phase distribution on the surface of the laser is

$$ϕ ( x , y ) = \frac{2 π}{λ} \times sin ( φ ) ,$$

wherein x is the transverse position, y is the longitudinal position, and λ is the wavelength.

The PCSEL/TCSEL laser module with integrated metalens of the present disclosure can also efficiently realize a variety of holographic images. There are two requirements for realizing clear holographic patterns: a sufficiently large coherent light area, and precise phase control. Both requirements are satisfied by the PCSEL/TCSEL laser module with integrated metalens of the present disclosure, but are difficult to be met by the conventional VCSEL laser array. In addition, the metalens has various control and multiplexing methods for polarization, and can achieve different holographic patterns with different polarization directions, which can be directly applied in the PCSEL/TCSEL laser module with integrated metalens of the present disclosure. In addition to far-field emission, the same is true for near-field design, such as focusing, near-field holography, and the like, where only a different design for the phase is required.

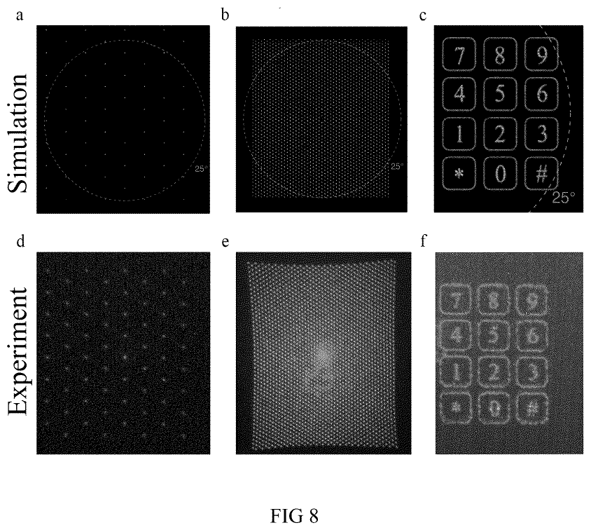

FIG. 8 is a simulation pattern and an experimental photograph of a point cloud structure and a far-field pattern realized by using a semiconductor laser of the present disclosure. In this regard, subfigures a and b are computer-simulated point cloud distribution of 8×16 and 48×48 dots, respectively, with a divergence angle of about 0.3° for individual dots and a field-of-view angle of 60°. Subfigure c is a computer-simulated holographic image of a digital keyboard. Subfigures d, e, and f are photographs of experimental results corresponding to subfigures a, b and c respectively, wherein the brighter dots are zero-order diffraction light spots, which can be solved through optimization design and processing. It can be seen that the PCSEL/TCSEL laser module with integrated metalens of the present disclosure is capable of realizing dot matrix cloud projection and holographic image with good quality.

In general, the surface-emitting semiconductor laser module realized by integrating a metalens on the surface of a PCSEL/TCSEL laser in the present disclosure has two main advantages. Firstly, it is small in size. More specifically, it is more than one order of magnitude smaller in size compared with the conventional VCSEL light source module, which is advantageous for cost reduction and application of high degree of integration. Secondly, it can be used for various functions. For example, it can emit light in an area of 1 mm×1 mm or larger with arbitrary polarization and arbitrary phase, which in turn can efficiently accomplish arbitrary structured light emission, deflection, holography and other functions. Based on these advantages, the device has potential applications in the fields of optical sensing, laser processing, optical display and the like. In particular, the Dirac vortex topological cavity in the TCSEL laser can provide a stable model-selection mechanism, and the metalens can integrally provide a comprehensive optical modulation function, so the laser module formed by the combination of the two will be an ideal semiconductor laser light source solution, which has very important and wide application prospects.

An exemplary embodiment of the present disclosure further provides an electronic device comprising the aforementioned PCSEL/TCSEL laser module integrated with metalens. The electronic device may be any electronic device using a laser light source, such as but not limited to, a portable electronic device such as a smartphone, a tablet computer, a laptop computer, a smart watch, a wearable electronic device, and the like. The electronic device may also comprise an in-vehicle electronic device, a smart home electronic device, a security electronic device, a display/projection device, and the like. In the electronic device, the PCSEL/TCSEL laser module with integrated metalens of the present disclosure can be used as a light source to realize corresponding functions, such as but not limited to face recognition, object detection, projection display and the like.

In addition, the laser module according to some embodiments of the present disclosure can also be applied in optical communication, enabling miniaturization and integration of optical communication devices using semiconductor lasers.

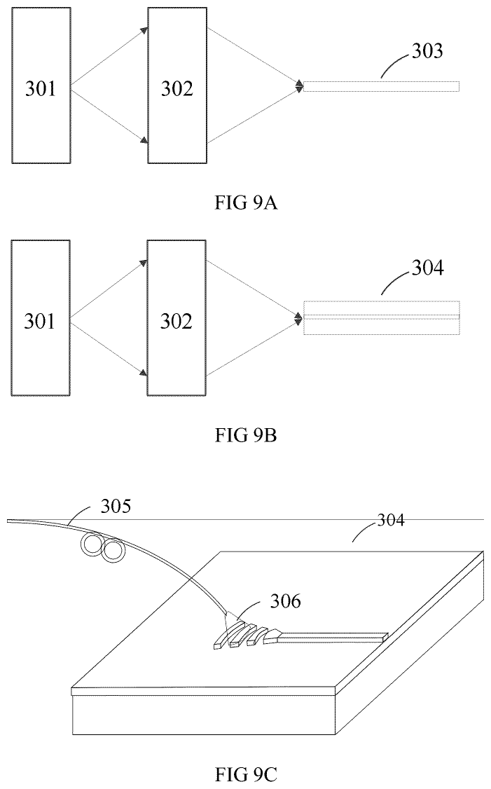

Optical communication mainly includes optical fiber communication and optical chip communication. Currently, coupling the semiconductor laser to the optical fiber usually uses optical lens coupling, and one or more lenses are added between the semiconductor laser and the optical fiber in such coupling mode, so as to improve the coupling efficiency. FIG. 9A shows a schematic structural diagram of a semiconductor laser-fiber coupling system in such a coupling manner. As shown in FIG. 9A, a modulated light beam is output from the light-emitting surface of a semiconductor laser 301, and a lens set 302 (including one or more lenses) is provided on the light path, which is used for focusing the light beam to a coupling surface of the optical fiber 303.

In the optical chip communication system, there are two main ways of coupling the semiconductor laser to the optical chip: surface coupling and edge coupling. For the edge coupling mode, a lens set usually needs to be added to improve the coupling efficiency. FIG. 9B shows a schematic structural diagram of a coupling system in which a lens set is added. As shown, the modulated light beam is output from the light-emitting surface of the semiconductor laser 301, and a lens set 302 is provided on the light path for focusing the light beam to the coupling edge of the optical waveguide 304. On the other hand, for the surface coupling mode, it is generally necessary to additionally introduce an optical fiber and tilt the optical fiber by a certain angle, due to the divergence angle of the conventional semiconductor laser and the second-order diffraction of the grating. As shown in FIG. 9C, in the surface coupling mode, the focused light beam is firstly coupled into the optical fiber 305, then the emission light beam 306 is tilted to emit into the grating on the surface of the on-chip optical waveguide 304.

However, though the efficiency can be improved through introducing a lens set into the semiconductor laser and fiber/on-chip optical waveguide coupling system, the problems of alignment and packaging are also introduced. The volume of the lens element is usually much larger than that of the semiconductor laser chip, thus it is difficult to reduce the size of the entire optical module. Moreover, in order to meet the alignment accuracy requirement, the packaging step needs to be performed with precision in the development and production of the optical components of the optical module. Therefore, the packaging cost is relatively high, which in turn limits the application of the coupling system to be more integrative and more cost-effective.

Compared to the conventional lasers that need a lens set to achieve optical fiber/on-chip optical waveguide coupling, some embodiments of the present disclosure directly integrate a metalens on the light-emitting surface of the semiconductor laser, which reduces the alignment step of the lens set in the subsequent packaging process while ensuring a high coupling efficiency, resulting in simplification of the packaging process, and further reduction of the device cost.

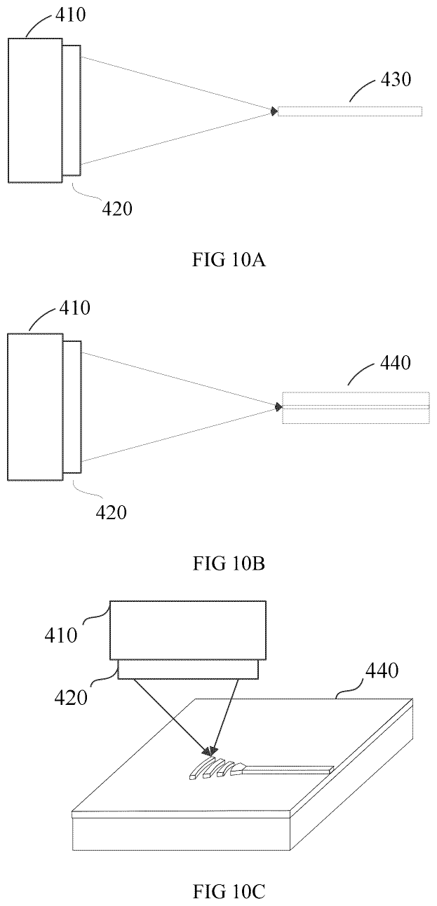

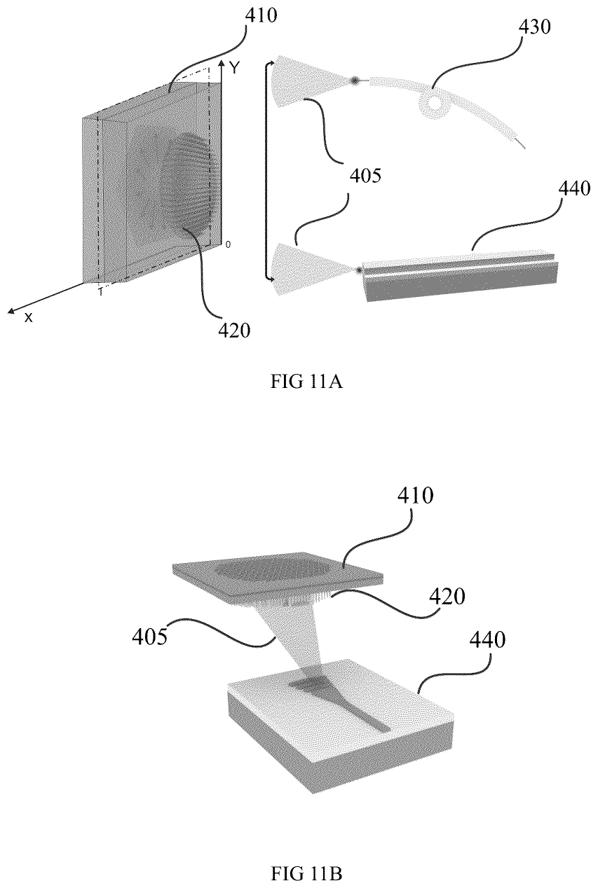

FIG. 10A shows a schematic structural diagram of a coupling system for coupling a semiconductor laser to an optical fiber according to an embodiment of the present disclosure. As shown, the coupling system includes a surface-emitting laser 410 which can be a photonic crystal surface-emitting laser (PCSEL), a topological cavity surface-emitting laser (TCSEL) or a vertical cavity surface emitting laser (VCSEL). Preferably, the surface-emitting laser 410 uses PCSEL or TCSEL, which can provide a larger light-emitting surface compared to VCSEL, for example, up to a millimeter-level aperture. Thus, integrating the metalens 420 on the single surface-emitting laser 410 can enable the emission light field to be manipulated in any degree of freedom (polarization, phase, wavelength, etc.) through a sub-wavelength scaled microstructure, and a well-coherent light source can be provided.

The integrated structure of the surface-emitting laser 410 and the metalens 420 is similar to the composition and structure of the surface-emitting laser 210 and the metalens 201 described with reference to FIGS. 2-5, and will not be repeated herein. For example, the metalens 420 (which may also be referred to as a metasurface) may be directly integrated into the light emission surface of the surface-emitting laser 410, for example, by etching micro-nano structure directly into the semiconductor layer on the emission surface to form the metalens, or an additional metalens layer may be deposited on the light emission surface in which a micro-nano structure may be etched out to form a metalens, or alternatively a micro-nano structure may also be directly deposited, grown or epitaxialized on the light-emitting surface of the surface-emitting laser to form the metalens. In this manner, the surface-emitting laser 410 and the metalens 420 form a single chip module.

As described above, the metalens 420 can arbitrarily regulate the polarization, phase, wavelength and other parameters of the laser beam. In an embodiment, the metalens 420 can achieve focusing the light beam emitted from the light-emitting surface of the surface-emitting laser 410 by means of the micro-nanostructure, so that the light beam output by the laser can be coupled into the optical fiber/on-chip optical waveguide, thereby eliminating the lens set, the additionally introduced tilted optical fiber, and the complicated alignment steps, in the conventional semiconductor laser-fiber coupling system.

The optical fiber 430 can be a standard single-mode optical fiber or a multi-mode optical fiber. Through position adjustment, the optical fiber 430 can be coupled to the light beam focused by the metalens 420. For example, the coupling end face of the optical fiber may be set to be located at the focusing focal length of the metalens, so as to realize optical coupling of the laser beam emitted by the laser 410 to the optical fiber 430. In an embodiment, the optical fiber 430 may be adjusted by an adjustment device (not shown) to adjust the position of the optical fiber 430 in the light path direction of the light beam so as to achieve a superior or optimal coupling efficiency.

FIGS. 10B-10C are schematic structural diagrams of a coupling system for coupling a semiconductor laser with an on-chip waveguide according to an embodiment of the present disclosure. Similar to the coupling system shown in FIG. 10A, the laser-waveguide coupling system also comprises a surface-emitting laser 410 with integrated metalens 420. That is, the surface-emitting laser 410 and the metalens 420 also form a single chip module. The difference is that the light beam emitted from the light-emitting surface of the surface-emitting laser 410 is optically coupled to the on-chip optical waveguide 440 after being focused by the metalens 420, comprising an edge-coupled mode (FIG. 10B) and a surface-coupled mode (FIG. 10C), which also eliminates the need for a lens set as well as an additional introduction of optical fibers in the conventional coupling system. In an embodiment, the on-chip optical waveguide 440 may be adjusted by an adjustment device to adjust its position in the optical path direction of the light beam to achieve a superior or optimal coupling efficiency.

In an embodiment, in a case where the on-chip optical waveguide uses a surface-coupled mode, a conventional method generally requires additionally introduction of an optical fiber and tilting the angle of the optical fiber to increase the coupling efficiency (see FIG. 9C). In contrast, according to an embodiment of the present disclosure, as shown in FIG. 10C, by designing or changing the structure of the integrated metalens 420, the laser beam can be emitted at an tilted angle, which can realize the on-chip coupling mode without optical fibers, and can reduce the size and complexity of the device.

In an embodiment, the on-chip waveguide 440 generally comprises a substrate and a waveguide layer formed thereon, and the waveguide layer may be, for example, a flat waveguide layer or a ridge waveguide layer. The specific structure of the on-chip waveguide is not limited herein, and it will be understood that various existing or future developed on-chip waveguides can be used in combination with the chip module of the integrated metalens surface-emitting laser module of the present disclosure so as to be applied in optical communication.

FIGS. 11A-11B show schematic diagrams of a three-dimensional spatial structure of a coupling system of a semiconductor laser with an optical fiber/waveguide according to an embodiment of the present disclosure. As shown, the coupling system mainly comprises a surface-emitting laser 410, a metalens 420, and an optical fiber 430 or an on-chip waveguide 440 (edge-coupling or surface-coupling). In this embodiment, the surface-emitting laser 410 is selected, for example, as a PCSEL or TCSEL laser with a size of approximately 1 mm×1 mm, which can realize an emission beam aperture equivalent to the laser module based on the VCSEL array. The thickness of the laser module can be reduced to approximately 300 m, and thus the volume of the whole laser module can be reduced by more than one order of magnitude, realizing the planarization and integration of the semiconductor laser light source of the coupling system. The metalens 420 is integrated at the light-emitting surface of the surface-emitting laser 410, such as a back side of the surface-emitting laser 410 (i.e., the upper surface of the surface-emitting laser 210 in FIG. 2). The metalens 420 comprises a nanopillar structure formed on the backside. A plurality of nanostructure units are (non-)periodically arranged on the backside of the laser 410 and are distributed in a substantially circular shape. The optical parameters of the material are used to realize the modulation of the polarization characteristic and the phase of the emission light, thus achieving the focusing function. The focused beam 405 is coupled into the optical fiber 430 or the on-chip waveguide 440, so that the data carried by the beam can be transmitted as optical pulses via the optical fiber 430 or can be transmitted through obliquely focusing into the on-chip waveguide 440 by edge coupling (FIG. 11A) or by surface coupling (FIG. 11B).

In an exemplary embodiment, the laser beam is coupled to the optical fiber 430. The original light spot of the laser 410 is, for example, a vector beam with a diameter of 500 m. After passing through the metalens 420 integrated on the backside, the light beam is focused at a focal length of 1.9 mm, with a focused spot size of 10 m. It shall be understood that this is only exemplary and not limiting. In an application scenario where a larger space is required, for example, where other elements such as an isolator need to be added between the semiconductor laser and the optical fiber, a larger metalens can be integrated on the back of the surface-emitting laser with a larger mode field area (e.g. 1 mm), so that a longer focal length can be obtained.

In some embodiments, the laser beam is coupled to the on-chip waveguide 440. For the edge-coupled mode, with reference to FIG. 11A, the original beam spot of the laser 410 is, for example, a vector light beam with a diameter of 500 m. After passing through the metalens 420 integrated on the backside, the beam is focused at a focal length of 80 m, with a focused spot size of 500 nm, so the volume of the coupling system is further reduced. It shall be understood that the beam spot size of the this embodiment is only an example, and for other systems of on-chip waveguides, such as silicon nitride, suitable focusing and focusing spot sizes can also be designed according to the corresponding waveguide dimensions. In some other embodiments, for the surface-coupled mode, referring to FIG. 11B, through adjusting the unit size of the metalens, the focusing beam can be made to tilt at a set angle (e.g. 10°), and the size of the focusing spot is 10 m, thus the surface coupling of the on-chip optical waveguide can be realized. As compared to the conventional surface-coupling mode via an optical fiber, embodiments of the present disclosure greatly reduces the size of the device, and simplifies the packaging alignment.

Referring back to FIG. 5, in an embodiment, one or more of the height h, the length l, the width s and the rotation angle θ of the nanopillar structure can be adjusted so as to adjust the phase, intensity and/or polarization and the like, of the laser beam emitted from the surface-emitting laser module, thus realizing focusing of the beam emitted from the laser.

Taking a topological cavity surface-emitting laser (TCSEL) as an example, the light beam emitted from the resonant cavity is a radially polarized vector beam. In order to transmit in, for example, a single-mode optical fiber 430 or an on-chip waveguide 440, it is necessary to convert the beam into a beam that can high-efficiently match the optical fiber/on-chip optical waveguide, e.g., by converting radially polarized vector light into linearly polarized light. At the same time, it is necessary to match the single-mode optical fiber's or the on-chip waveguide's numerical aperture (NA) and the mode field diameter. Therefore, the nanopillar structure of the metalens firstly needs to be designed to play the role of a half-wave sheet. For example, the long-axis direction of the nanopillar unit of the metalens structure is at an angle of θ=φ/2 with the laser polarization direction, where φ is the polar angle of the radial vector polarization with respect to the x-axis. The transmission phase Øₗ in the long-axis direction and the transmission phase Øₛ in the short-axis direction satisfy Øₗ−Øₛ=π, where the transmission phase Øₛ in the short-axis direction can be modulated in the range of 0−π, so as to adjust the emission phase of the linearly polarized light.

Similarly, in order to prevent the high-order reflection, the arrangement period P of the nanopillar structure shall be less than

$$\frac{2}{\sqrt{3}} \frac{λ}{{n}_{lnP}} ,$$

where n_{Inp} is the refractive index of InP. The period P is selected to be, for example, 558 nm, the height h of the nanopillar is 1.5 m, the length range of the rectangular short-side s is selected to be from 100 nm to 250 nm, preferably from 120 nm to 244 nm, and the long side l is selected to be in a range from 350 nm to 450 nm, preferably from 382.7 nm to 438.4 nm.

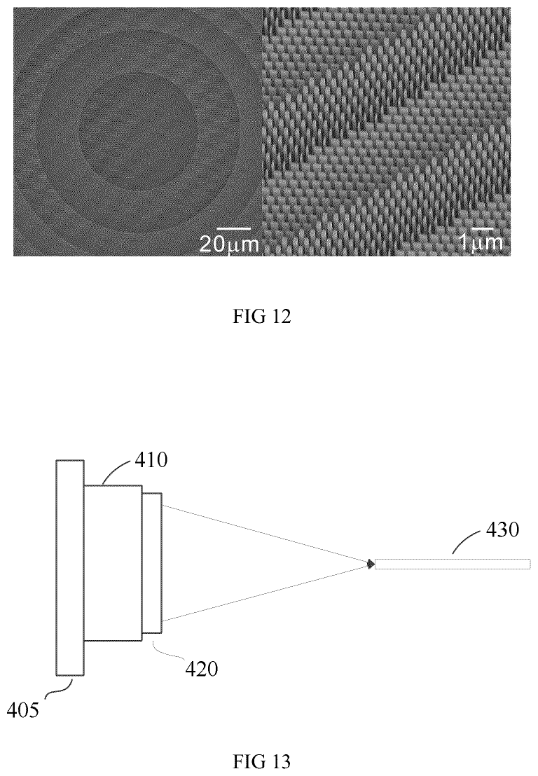

The focusing characteristics of the metalens are also affected by the parameters such as s and l of the nanopillar unit and the arrangement design of the nanopillar. That is, the focal length f can also be adjusted by the structure design of the nanopillar. FIG. 12 is an electron microscope SEM photograph of a nanopillar structure forming the metalens 220. This example is a metalens structure obtained by processing through UV exposure, electron beam lithography, and a dry etching process after depositing amorphous silicon on an InP substrate (e.g. a second semiconductor layer 218).

As shown in FIG. 12, at a resolution of 1 m, a number of adjacent nanopillar structure units in the radial direction of the metasurface have the same rotation angle. Meanwhile, at a resolution of 20 m, the metasurface as a whole consists of a number of nanostructure units in circular arrangement, i.e., the nanostructure units are arranged to form a number of circular rings. The radial period in the circular periodic arrangement can be selected as a subwavelength scale, so as to facilitate the regulation of the laser beam.

In the example, referring to FIG. 11, taking the coupling the semiconductor laser with the optical fiber as an example, the focal length f of the metalens has a size of 1.9 mm, and the size of the diameter of the focusing spot is 10 m. According to the NA calculation formula (3), it is obtained that the NA of the output spot of the surface-emitting laser 410 with integrated metalens is NA=0.13. The spot diameter and the NA are comparable to the mode field diameter and NA of the single-mode optical fiber 430, respectively. Therefore, the emitted beam can be well optically coupled to the optical fiber 430.

$$NA = \frac{D}{2 f} \qquad ( formula 3 )$$

It shall be noted that, in this embodiment, a topological cavity surface-emitting laser with a mode field diameter of 500 m is selected to illustrate the principle of the present disclosure, and the focal length of the metalens is accordingly about 1.9 mm. In practical applications where a larger space is required, for example, where other elements such as an isolator need to be added between the semiconductor laser and the optical fiber, a larger metalens can be integrated on the back of the surface-emitting laser with a larger mode field area (e.g. 1 mm), and a longer focal length can be obtained. In some embodiments, by adjusting the structural parameter of the metasurface, the metasurface can emit a plurality of focusing spot, that is, the emitted beam is focused on a plurality of focal points, which can be coupled into a plurality of optical fibers or on-chip waveguides, respectively.

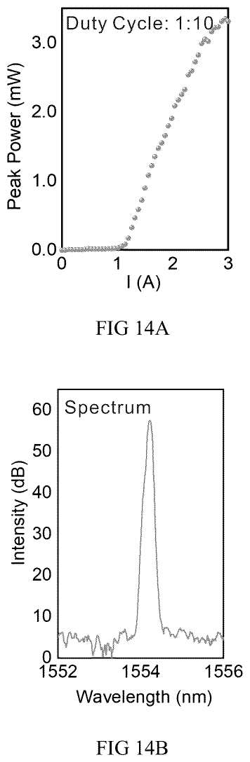

In order to verify the technical advantages and the application prospects of the present disclosure, an optical test can be performed on the coupling system of a prepared surface-emitting laser with integrated metalens and an optical fiber. In an example, an integrated optical chip can be mounted on a TO (transistor outline) base. FIG. 14 shows a schematic diagram of the optical test mounting structure. As shown, the surface-emitting laser TCSEL chip module with integrated metalens is mounted on the TO base 405, and the single-mode optical fiber 430 can be fixed by a clamping device (not shown) on the three-dimensional displacement table, and the optical fiber is aligned with the laser chip. For example, the distance between the optical fiber end face and the laser chip can be adjusted so that the two can be optically coupled, i.e., the metalens focuses the light beam to the coupling end face of the optical fiber. It is to be understood that those skilled in the art can also build a system for coupling a surface-emitting laser to an on-chip waveguide for optical testing.

In this embodiment, the surface laser chip module with integrated metalens may enable miniaturization of the device. The whole module only needs a semiconductor chip of about 100 micrometers thick, with the area of the chip being determined by the diffraction limit and the focusing focal length of the application requirements. In contrast, the coupling of a conventional semiconductor laser with optical fibers/waveguide needs to introduce a single or multiple lenses, so the overall device size is usually in the magnitude of millimeter. Therefore, compared to a conventional module, the longitudinal thickness of the laser chip module of the embodiments of the present disclosure is reduced by 1-2 orders of magnitude, which also makes the weight of the whole device be lighter due to without using the conventional lens.

As compared to conventional coupling systems, the coupling system of the present disclosure also significantly reduces the difficulty of alignment due to the elimination of the need for the lens. In the conventional method of coupling a semiconductor laser to an optical fiber/waveguide, the lens will introduce new alignment uncertainties during the coupling process, which complicates the packaging step, and therefore increases the cost of the packaging process. On the other hand, the aligned lens needs to be fixed at a specific position of the device by means of glue solidification, and the tolerance of the fixed position is only submicron, thus requiring very precise fixation equipment. However, with the use of the optical device, the glue used for fixing the lens may probably move due to uncertain factors such as temperature, causing the position to shift and the optical path to bend, leading to failure of the optical device.

Different from the conventional coupling mode, in the design of the embodiment of the present disclosure, a metalens is directly integrated on the back of the surface-emitting semiconductor laser, which may reduce the coupling alignment step of the lens in conventional alignment operation, and then only need to adjust the position of the optical fiber/waveguide to obtain better or optimal coupling efficiency. The problem that the lens is shifted due to high temperature will not occur. The packaging difficulty can be greatly reduced, and the cost of the whole optical module device can be reduced.

The advantages in terms of coupling efficiency of the coupling system for the integrated metalens and the surface-emitting laser in the embodiments of the present disclosure are further described below.

Currently, semiconductor lasers used for optical communication at 1550 nm/1310 nm (wavelength) are edge-emitting semiconductor lasers, e.g., distributed feedback (DFB) lasers. The coupling of the DFB to optical fibers/waveguide generally uses a single spherical lens, or includes an aspheric lens and a cylindrical lens set, according to actual application requirements. Among them, the single spherical lens is mostly used for applications with low power requirement. Due to the different focusing effects of the spherical lens on the long axis and the short axis of the emission light from the edge-emitting laser, the single spherical lens is likely to lead to a mismatch of the mode field of the focused beam with the intrinsic fundamental mode of the optical fiber/waveguide. In a single spherical lens coupling system, the coupling efficiency from the DFB to the optical fiber is typically only about 20%. In a system with high power requirements, a multi-lens module can be used. For example, an aspheric lens is introduced to correct the spherical aberration, so that the coupling efficiency can achieve 50%. Introducing a three-lens module with two cylindrical lenses plus an aspheric lens can make the coupling efficiency reach 80%, but as described earlier for the alignment process, the introduced extra lens set will greatly increase the difficulty of alignment and bring about an increase in packaging costs.

Different from DFB, in the design of the embodiment of the present disclosure, due to the excellent beam quality of the surface-emitting laser, a focused beam with close to 100% matching to the single-mode optical fiber/waveguide mode field and NA can be theoretically obtained by using only a single integrated metalens. Even considering that the metalens may experience close to 10% zero-order diffraction during actual machining process, the final experimental efficiency can theoretically reach about 90%. The coupling efficiency of the optical chip of this embodiment can be tested by using the experimental device in FIG. 13, e.g., by mounting a surface-emitting semiconductor laser with an integrated metalens on a TO base, and placing a single-mode optical fiber on a three-axis displacement table for testing. FIG. 14A shows a power input-light intensity output (Li) curve of the device, and FIG. 14B shows the spectrogram of the device. The center alignment and the focal length of the single-mode optical fiber with the optical chip are adjusted through the displacement table, and a test efficiency of 50% is obtained. The process does not need the introduction of any lens, and the coupling process of the embodiments of the present disclosure is much simpler than that of the conventional system that introduces separate lens elements.

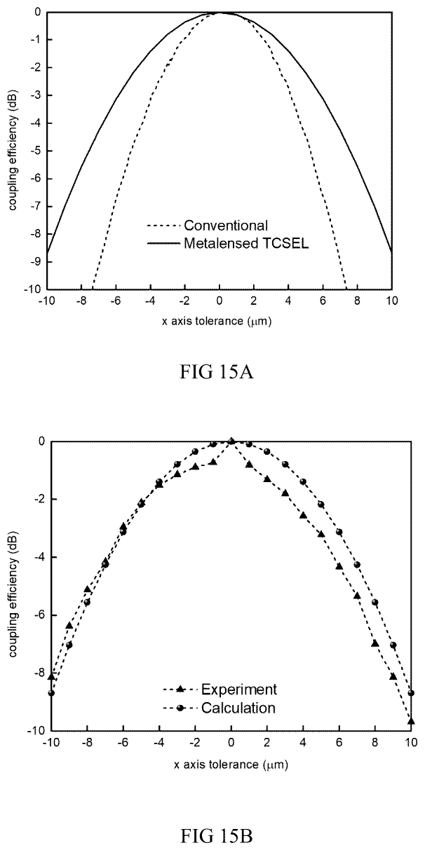

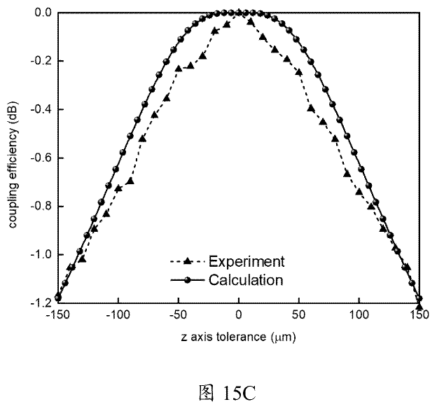

FIGS. 15A-15C show the coupling tolerances of the system in the z-axis direction and the x-y direction, where the coupling efficiency is obtained by moving the optical fiber along the x/z axis and testing, wherein FIG. 15A shows a comparison of the tolerance computation in the x-direction between the embodiment of the present disclosure and the conventional DFB coupling system, FIG. 15B shows an experimental and computational comparison of the two for tolerance tests in the x-axis direction, and FIG. 15C shows an experimental and computational comparison of the two for tolerance test in the z-axis direction. As can be seen, compared with the conventional coupling method, in the embodiment of the present disclosure, the coupling tolerance is better due to the excellent beam quality of the surface-emitting laser, and the absence of the need for introduction of separate lens elements. Meanwhile, the coupling efficiency between the topological cavity surface-emitting laser TCSEL with integrated metalens and the optical fiber can be greatly improved. Compared to a coupling system using lenses, in the embodiment of the present disclosure, the alignment difficulty of the device will be greatly reduced while the coupling efficiency is ensured, and the whole optical device will be more friendly in terms of cost.

According to the technical solution of the embodiments of the present disclosure, an fiber coupling system without a lens module is designed and implemented based on a surface-emitting semiconductor laser with an integrated metalens. Since there is no need to introduce a conventional lens, the alignment difficulty during the packaging process is greatly reduced. Due to the integrated design, the device size is reduced by 1-2 orders of magnitude in thickness compared to conventional semiconductor lasers with lens module systems. In addition, the optical device according to embodiments of the present disclosure emits beams of high quality, with a mode field area and NA consistent with those of a single-mode optical fiber, thereby it achieves a superior coupling efficiency than the conventional module.

The above description has been provided for the purposes of illustration and description. This description is not intended to limit the embodiments of the present disclosure to the forms disclosed herein. Although various exemplary aspects and embodiments have been discussed above, those skilled in the art will recognize certain variations, modifications, alterations, additions and sub-combinations thereof.

Although some embodiments of the present disclosure have been described, these embodiments are presented as examples only and are not intended to limit the scope of the present invention. In fact, the novel methods and systems described in this disclosure may be implemented in various other forms. In addition, various omissions, substitutions, and changes may be made in the form of the methods and systems described in this disclosure without departing from the scope of this disclosure.

What is claimed is:

1. A surface-emitting laser module integrated with a metalens, comprising:
a surface-emitting laser comprising a photonic crystal surface-emitting laser or a topological cavity surface-emitting laser, the surface-emitting laser having a light-emitting surface; and
a metalens integrated at the light-emitting surface of the surface-emitting laser.

2. The surface-emitting laser module of claim 1, wherein an upper surface of a top layer of the surface-emitting laser is used as the light-emitting surface of the surface-emitting laser, and
the metalens comprises a nanopillar structure or a nanopore structure formed in the upper surface of the top layer.

3. The surface-emitting laser module of claim 2, wherein the top layer of the surface-emitting laser is a semiconductor layer, an insulating layer, or a metal layer.

4. The surface-emitting laser module of claim 1, wherein an upper surface of a top layer of the surface-emitting laser is used as the light-emitting surface of the surface-emitting laser, and
the metalens comprises a nanopillar structure or a nanopore structure formed above the top layer.

5. The surface-emitting laser module of claim 4, wherein the nanopillar structure is formed in a metalens layer disposed above the top layer of the surface-emitting laser, the metalens layer being etched partially or entirely through its thickness to form the nanopillar structure, or
the nanopillar structure is formed by depositing, growing or epitaxializing a nanopillar structure directly on the top layer of the surface-emitting laser.

6. The surface-emitting laser module of claim 4, wherein the nanopillar structure comprises a semiconductor material, an insulator material, a metallic material, an organic material or a transparent conductive material.

7. The surface-emitting laser module of claim 4, wherein the nanopillar structure comprises one or more of amorphous silicon, titanium dioxide, silicon nitride, silicon oxide, alumina, and hafnium dioxide.

8. The surface-emitting laser module of claim 2, wherein the metalens comprises a rectangular or elliptical nanopillar structure, the nanopillar structure being arranged in a triangular lattice or a tetragonal lattice, and each nanopillar structure having a height h, a length l, a width s, and a rotation angle θ.

9. The surface-emitting laser module of claim 8, wherein one or more of the height h, the length l, the width s, and the rotation angle θ of the nanopillar structure is modulated to adjust a phase, an intensity, and/or a polarization of a laser emitted from the surface-emitting laser module.

10. An electronic device comprising a surface-emitting laser module, wherein the surface-emitting laser module comprises:
a surface-emitting laser comprising a photonic crystal surface-emitting laser or a topological cavity surface-emitting laser, the surface-emitting laser having a light-emitting surface; and
a metalens integrated at the light-emitting surface of the surface-emitting laser.

11. A laser coupling system, comprising:
a surface-emitting laser comprising a photonic crystal surface-emitting laser or a topological cavity surface-emitting laser, the surface-emitting laser having a light-emitting surface;
a metalens integrated at the light-emitting surface of the surface-emitting laser for focusing a light beam emitted from the light-emitting surface; and
an optical fiber or on-chip optical waveguide configured to couple with the focused light beam.

12. The laser coupling system of claim 11, wherein the metalens is configured to convert a light beam emitted from the light-emitting surface into a light beam that can be matched to the optical fiber or on-chip optical waveguide.

13. The laser coupling system of claim 11, wherein the optical fiber is a single-mode fiber or a multimode fiber, and the on-chip optical waveguide is in an edge-coupled mode or a surface-coupled mode.

14. The laser coupling system of claim 11, wherein the emitted light beam is focused at one or more focal points and coupled to a single or more optical fibers or on-chip optical waveguides.

15. The laser coupling system of claim 11, wherein an upper surface of a top layer of the surface-emitting laser is used as the light-emitting surface of the surface-emitting laser, and the metalens comprises a nanopillar structure or a nanopore structure formed in the upper surface of the top layer.

16. The laser coupling system of claim 15, wherein the nanopillar structure comprises a semiconductor material, an insulator material, a metallic material, an organic material or a transparent conductive material.

17. The laser coupling system of claim 15, wherein the nanopillar structure comprises one or more of amorphous silicon, titanium dioxide, silicon nitride, silicon oxide, alumina, and hafnium dioxide.

18. The laser coupling system of claim 15, wherein the nanopillar structure is arranged in a non-periodic manner, each nanopillar structure having a height h, a length l, a width s, and a rotation angle θ, and wherein one or more of the height h, the length l, the width s, and the rotation angle θ of the nanopillar structure is modulated to adjust a phase, intensity, and/or polarization of a light beam emitted from the surface-emitting laser.

19. The laser coupling system of claim 18, wherein the length l ranges from 350 nm to 450 nm, and the width s ranges from 100 nm to 250 nm.
